(19) United States
(12) Patent Application Publication
(10) Pub. No.: US 2008/0088322 A1
(43) Pub. Date: Apr. 17, 2008

(54) Semiconductor device fabrication method and semiconductor device

(75) Inventor: Kouichi Nagai, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/905,278

(22) Filed: Sep. 28, 2007

(30) Foreign Application Priority Data
Sep. 29, 2006 (JP) 2006-267856

(51) Int. Cl. G01R 27/26; H01L 21/311

(52) U.S. Cl. 324/671; 438/50; 257/E21.249

(57) ABSTRACT

A semiconductor device having sufficient sensitivity, strength, and the like and a method for fabricating such a semiconductor device. In a method for fabricating a semiconductor device which detects the shape of a skin surface by detecting capacitance formed between the skin surface and a conductive film between which a passivation film including a silicon nitride film and a polyimide film is, the polyimide film with a thickness of not less than 400 nm nor more than 700 nm is formed at a curing temperature higher than or equal to 350° C. and lower than or equal to 380° C. as a top layer of the semiconductor device. When the polyimide film is cured, nitrogen gas or the like is made to flow in at a flow rate of 110 liters/minute or more. By adopting this method, a very thin passivation film is formed on a semiconductor device and a semiconductor device having sufficient sensitivity, strength, and the like can be fabricated.

### CROSS-REFERENCE TO RELATED APPLICATIONS

This application is based upon and claims the benefits of priority from the prior Japanese Patent Application No. 2006-267856, filed on Sep. 29, 2006, the entire contents of which are incorporated herein by reference.

### TECHNICAL FIELD

This invention relates to a semiconductor device fabrication method and a semiconductor device.

### BACKGROUND

With the development of an information-oriented society, interest in security techniques has developed. In the information-oriented society, an individual authentication technique for building electronic cashing systems and the like is an important key. Accordingly, attention is riveted on an individual authentication technique by a fingerprint.

A capacitance type fingerprint sensor fabricated by using an LSI has recently been developed especially from the viewpoint of miniaturization and ease of fabrication (see U.S. Pat. No. 7,045,379).

This sensor detects an irregular pattern of skin by sensing feedback capacitance with a plurality of sensors two-dimensionally arranged on an LSI chip.

With the capacitance type fingerprint sensor, a sensor electrode is formed over a semiconductor substrate. A passivation film is formed over the sensor electrode and the semiconductor substrate. Capacitance formed between a skin surface and the sensor electrode which the passivation film is between is detected and the irregular shape of the skin surface is detected. The principles underlying the capacitance type fingerprint sensor will now be described.

FIGS. 1A and 1B are partially schematic views for describing the principles underlying the capacitance type fingerprint sensor. FIG. 1A is a partially schematic sectional view showing the fingerprint sensor which is a kind of semiconductor device. FIG. 1B is a partially schematic plan view showing the fingerprint sensor.

With this capacitance type fingerprint sensor, as shown in FIG. 1A, a wiring layer 102 is located over a semiconductor substrate 100 on which an LSI and the like are formed with an insulating layer 101 between the wiring layer 102 and the semiconductor substrate 100. An insulating layer 103 is located over the wiring layer 102 and the insulating layer 101.

A sensor electrode 104 having, for example, a rectangular shape is formed over the insulating layer 103. The sensor electrode 104 is connected to the wiring layer 102 via a contact plug 105 in a contact hole made in the insulating layer 103.

A passivation film 106 is formed of, for example, silicon nitride (SiN) over the insulating layer 103 so as to cover the sensor electrode 104. By doing so, a sensor element is formed. As shown in FIG. 1B, a plurality of sensor elements each including the above components are two-dimensionally arranged so that the sensor electrodes 104 included in adjacent sensor elements will not touch each other.

Next, the operation of the capacitance type fingerprint sensor will be described. When a fingerprint is detected, a finger the fingerprint of which is to be detected touches the passivation film 106 first. When the finger touches the surface of the passivation film 106, the skin which touches the passivation film 106 functions as an electrode over the sensor electrode 104. As a result, capacitance is formed between the skin and the sensor electrode 104. This capacitance is detected by a detection section (not shown) via the wiring layer 102. The fingerprint at a fingertip is formed of irregularities of the skin. Therefore, when the finger touches the passivation film 106, there is a difference in the distance between the skin as an electrode and the sensor electrode 104 between convex portions and concave portions which make up the fingerprint.

The difference in the distance between the skin as an electrode and the sensor electrode 104 is detected as a difference in capacitance. Accordingly, by detecting distribution of different capacitance values, the shape of the convex portions of the fingerprint is obtained. That is to say, the capacitance type fingerprint sensor can sense the state of the minute irregularities of the skin.

As stated above, to protect the surface of a semiconductor device including the capacitance type fingerprint sensor, the passivation film 106 which is, for example, an SiN film covers the surface of the semiconductor device.

An organic polyimide film has recently been used as a passivation film so that the passivation film will have a shock absorbing characteristic (see, for example, Japanese Patent No. 3,630,483).

Usually a polyamic acid type polyimide is used for forming such a polyimide film. In this case, a polyimide film with a thickness of 3,000 nm is formed at a temperature of about 320 to 380° C.

To make the passivation film formed on the semiconductor device function fully, it is desirable that the passivation film should be thickened or that the passivation film should have a laminated structure including several layers.

With the capacitance type fingerprint sensor, however, the distance between the sensor electrode and the finger which touches the surface of the sensor becomes long if a thick passivation film is formed or if the passivation film has a laminated structure including several layers. As a result, capacitance formed between the sensor electrode and the surface of the sensor decreases and the sensitivity to detect a fingerprint becomes extremely low.

To improve the sensitivity of the capacitance type fingerprint sensor, it is desirable that the distance between the sensor electrode and the surface of a finger should be reduced. Accordingly, it is desirable that the passivation film should be thinned.

Therefore, with conventional capacitance type fingerprint sensors, a polyamic acid type polyimide film is thinned up to the limit and the polyimide film with a thickness of about 1,000 nm is formed. However, if a thinner polyamic acid type polyimide film is formed, the strength of the film itself falls. Accordingly, it is difficult to form a polyamic acid type polyimide film 1,000 nm or less in thickness.

On the other hand, a polyamic ester type polyimide has recently been developed. As a result, polyimide by which imide can be formed at a low temperature compared with the polyamic acid type polyimide has appeared. Experiments show that the strength of a polyamic ester type polyimide film is slightly higher than that of a polyamic acid type polyimide film of the same thickness. The strength of a polyimide film 800 nm or more in thickness in a capacitance type fingerprint sensor in which the polyamic ester type polyimide is used is the same as that of a polyimide film in a capacitance type fingerprint sensor in which the polyamic acid type polyimide is used. However, if a polyamic ester type polyimide film is 800 nm or less in thickness, the reliability of a passivation film deteriorates. In addition, if high temperature curing is performed from the first on the polyamic ester type polyimide, a uniform imide film cannot be formed. The likely reason for this is that compared with the polyamic acid type polyimide, temperature at which imide reacts is low. When the polyamic ester type polyimide was rapidly heated, part of a film burst in some cases. The polyamic ester type polyimide was originally developed so that it will cross-link at a low temperature. Accordingly, the polyamic ester type polyimide cannot be used for forming a polyimide film at a high temperature higher than or equal to 320° C. or there is no guarantee that the polyamic ester type polyimide can be used for forming a polyimide film at a high temperature higher than or equal to 320° C.

That is to say, if the polyamic acid type polyimide is used for forming a polyimide film 1,000 nm or less in thickness, the strength of the film is not sufficient to withstand friction with a finger. On the other hand, if the polyamic ester type polyimide is used for forming a polyimide film 800 nm or less in thickness, the strength of the film is not sufficient to withstand friction with a finger. In addition, if high temperature curing is performed, a uniform imide film cannot be formed.

### SUMMARY

The present invention is directed to various embodiments of a method for fabricating a semiconductor device and a semiconductor device which detect the shape of a skin surface, having an insulating film with a thickness of not less than 400 nm nor more than 700 nm.

### BRIEF DESCRIPTION OF THE DRAWINGS

FIGS. 1A and 1B are partially schematic views for describing the principles underlying the capacitance type fingerprint sensor, FIG. 7(A) being a partially schematic sectional view showing the fingerprint sensor which is a kind of semiconductor device, FIG. 7(B) being a partially schematic plan view showing the fingerprint sensor.

FIG. 2 is a flow chart showing a method for forming a passivation film.

FIG. 3 is a partially schematic sectional view showing a process for fabricating a semiconductor device.

FIGS. 4A and 4B are partially schematic sectional views showing the process for fabricating the semiconductor device.

FIG. 5 is a view for describing fingerprint images read by capacitance type fingerprint sensors.

FIG. 6 is a view for describing the strength of polyimide films.

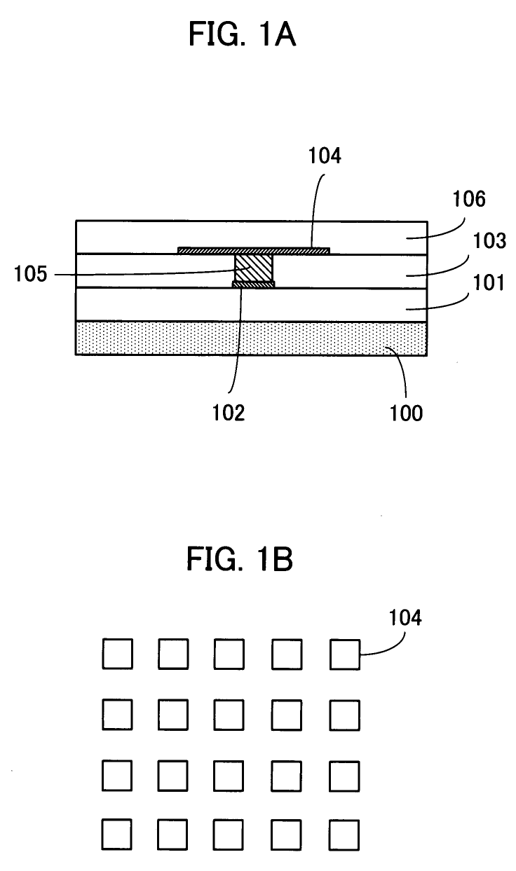

### DETAILED DESCRIPTION OF THE PREFERRED EMBODIMENTS

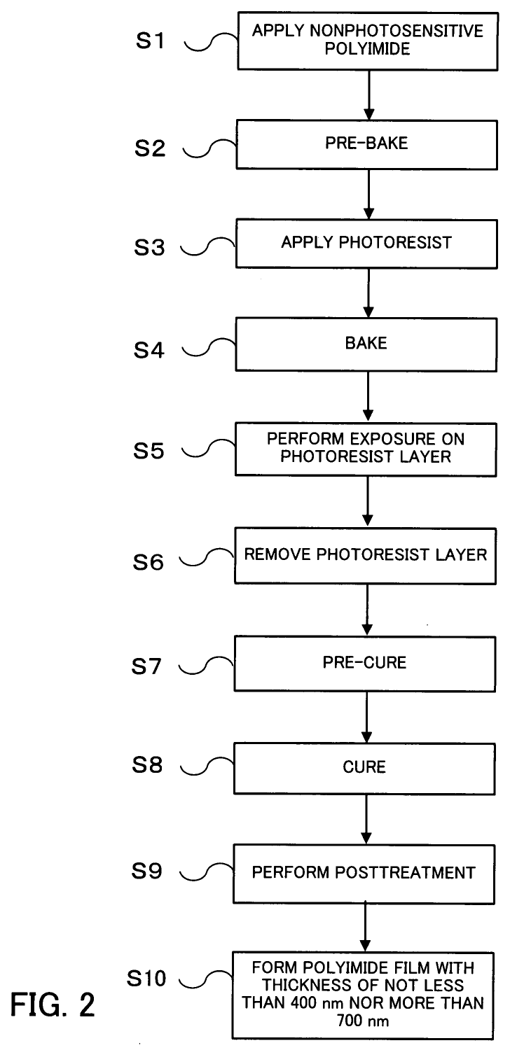

FIG. 2 is a flow chart showing a method for forming a passivation film.

A silicon nitride (SiN) film, for example, is formed first over a semiconductor device including a sensor electrode as an insulating film which is a first passivation film. Nonphotosensitive polyimide, for example, is then applied over the SiN film as an insulating film which is a second passivation film (step S1). The nonphotosensitive polyimide film is then pre-baked (step S2). To perform patterning on the nonphotosensitive polyimide film, photoresist is then applied over the nonphotosensitive polyimide film (step S3). The photoresist layer is then baked (step S4). Exposure is then performed on the photoresist layer (step S5). After that, the photoresist layer is developed and is removed from over the nonphotosensitive polyimide film (step S6). When the photoresist layer is removed from over the nonphotosensitive polyimide film, a pattern has been formed in the nonphotosensitive polyimide film.

After the nonphotosensitive polyimide film in which the pattern is formed is dried, the nonphotosensitive polyimide film is pre-cured in a predetermined atmosphere at a predetermined temperature (step S7). The nonphotosensitive polyimide film is then cured in a predetermined atmosphere at a predetermined temperature to harden the nonphotosensitive polyimide film (step S8). Lastly, posttreatment is performed to harden the nonphotosensitive polyimide film further (step S9). The nonphotosensitive polyimide film the final thickness of which is 400 to 700 nm is formed as a top layer of the semiconductor device (step S10).

By using the above method, a passivation film which is a very thin nonphotosensitive polyimide film can be formed as the top layer of a semiconductor device including a capacitance type fingerprint sensor.

If photosensitive polyimide is used in place of nonphotosensitive polyimide, steps S3, S4, and S6 included in the above method are omitted and exposure is performed directly on photosensitive polyimide in step S5. By performing exposure directly on photosensitive polyimide and performing patterning, a passivation film including a photosensitive polyimide film can be formed as a top layer of the semiconductor device. Polyimide used is the polyamic ester type polyimide or the like.

As stated above, the semiconductor device including a capacitance type fingerprint sensor detects capacitance formed between a skin surface and a conductive film between which an insulating layer that is a passivation film including the SiN film and the polyimide film is. The polyimide film with a thickness of 400 to 700 nm is formed as a top layer of the semiconductor device.

By adopting the above method for forming a passivation film, a very thin polyimide film which is a passivation film is formed as the top layer. Accordingly, the distance from the sensor electrode included in the semiconductor device including a capacitance type fingerprint sensor to the surface of a finger skin can be shortened. As a result, capacitance formed between the sensor electrode and the skin surface between which the passivation film is can be increased and sensitivity to detect the irregular shape of a fingerprint can be improved.

Even a very thin polyimide film has sufficient mechanical strength, so the reliability of the semiconductor device is equal to or higher than that of conventional semiconductor devices.

In addition, a very thin polyimide film is formed, so the distance between an electrostatic discharge (ESD) hole portion (described later) and the surface of the polyimide film is shortened. Therefore, electric charges on the surface of the polyimide film tend to diffuse into the ESD hole portion. As a result, the influence of the electric charges on the capacitance formed between the sensor electrode and the skin surface can be reduced and the sensitivity of a capacitance type fingerprint sensor can be improved.

A polyimide film with a thickness of 400 nm or less may be formed to further improve sensitivity to detect a fingerprint. However, if a polyimide film with a thickness of 400 nm or less is formed, an effect as a shock absorbing material weakens further and the strength of the polyimide film weakens further. As a result, high reliability cannot be guaranteed (for example, polyimide may be damaged by scrubbing with a finger). Therefore, it is desirable that a polyimide film with a thickness of 400 nm or more should be formed.

The method for forming the passivation film as the top layer of the semiconductor device including a capacitance type fingerprint sensor will now be described concretely. In this embodiment, the method for forming the passivation film as the top layer of the semiconductor device which includes a capacitance type fingerprint sensor and in which complementary metal oxide semiconductor (CMOS) transistors are formed will be described concretely.

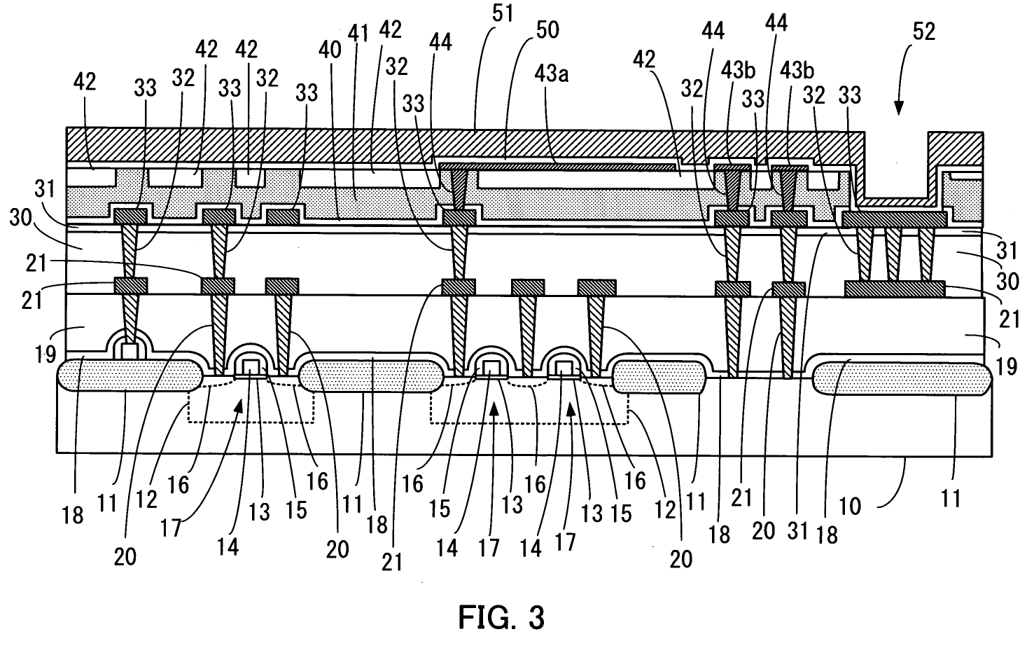

FIG. 3 is a partially schematic sectional view showing a process for fabricating the semiconductor device.

FIG. 3 shows an example of a semiconductor device in which CMOS transistors are formed, and is a partially schematic view showing the semiconductor device including a capacitance type fingerprint sensor.

A state in which the silicon nitride film that is the passivation film has been formed as an upper layer of the semiconductor device including a capacitance type fingerprint sensor will be outlined first.

With this semiconductor device, isolation regions 11 for defining element regions are formed over, for example, a silicon (Si) substrate 10. Wells 12 are formed in the Si substrate 10. A gate electrode 14 is formed over each well 12 with a gate insulating film 13 between.

An insulating layer 15 used as sidewalls is formed on the sides of each gate electrode 14. Source/drain regions 16 are formed on both sides of each gate electrode 14 on the sides of which the insulating layer 15 is formed.

MOS transistors 17 included in a CMOS are formed in this way on the Si substrate 10.

A silicon oxide nitride (SiON) film 18 with a thickness of 200 nm is formed over the Si substrate 10. A TEOS (tetraethyl orthosilicate (TEOS)-nondoped silicate glass (NSG) film 19 with a thickness of 800 nm which is an interlayer dielectric film is formed over the SiON film 18.

A tungsten (W) layer 20 used as bulk contacts pierce the TEOS-NSG film 19 and the SiON film 18 and is electrically connected to the source/drain regions 16 and the gate electrode 14. In addition, the W layer 20 is electrically connected to a first aluminum (Al) wiring layer 21 formed over the TEOS-NSG film 19 by patterning.

A TEOS-NSG film 30 with a thickness of 1,200 nm which is an interlayer dielectric film is formed over the Al wiring layer 21. A TEOS-NSG film 31 with a thickness of 100 nm is formed over the TEOS-NSG film 30.

A W layer 32 used as bulk contacts is formed over the Al wiring layer 21 so that it will pierce the TEOS-NSG films 30 and 31. In addition, the W layer 32 is electrically connected to a second Al wiring layer 33 formed over the TEOS-NSG film 31 by patterning.

A TEOS-NSG film 40 with a thickness of 400 nm is formed over the second Al wiring layer 33. A spin on glass (SOG) film 41 with a thickness of 500 nm is formed over the TEOS-NSG film 40. A TEOS-NSG film 42 with a thickness of 300 nm is formed over the SOG film 41.

Titanium nitride (TiN) films 43a and 43b with a thickness of 200 nm are formed as patterns over the SOG film 41 and the TEOS-NSG film 42. The TiN film 43a is used as a sensor electrode of the semiconductor device including a capacitance type fingerprint sensor. The longitudinal length of the rectangular TiN film 43a from above the semiconductor device is 50 μm. The TiN film 43b is grounded to prevent ESD caused by the charged surface of a polyimide film (described later). The TiN films 43a and 43b are electrically connected via the second Al wiring layer 33 and a TiN layer 44.

A TEOS-NSG film 50 with a thickness of 100 nm is formed over the TiN films 43a and 43b. An SiN film 51 with a thickness of 700 nm which is the first passivation film is formed over the TEOS-NSG film 50. The SiN film 51 over a pad portion 52 of the semiconductor device is deeply etched. A nitride film, such as an SiN film, or an oxide nitride film, such as an SiON film, may be used as the first passivation film. The second passivation film (described later) is formed over the first passivation film.

As has been described, the integrated circuit, the W layers 20 and 32, and multilayer wiring layers including the Al wiring layers 21 and 33 are formed over the Si substrate 10 in this process.

In the multilayer wiring layers, a plurality of wirings are connected to a plurality of elements including the MOS transistors 17. In addition, the multilayer wiring layers are electrically connected to the TiN film 43a used as the sensor electrode and form a sensor circuit and the like. An interlayer dielectric film is formed between wiring layers and a plurality of interlayer dielectric films are formed in the semiconductor device. The top layer is covered with the SiN film 51.

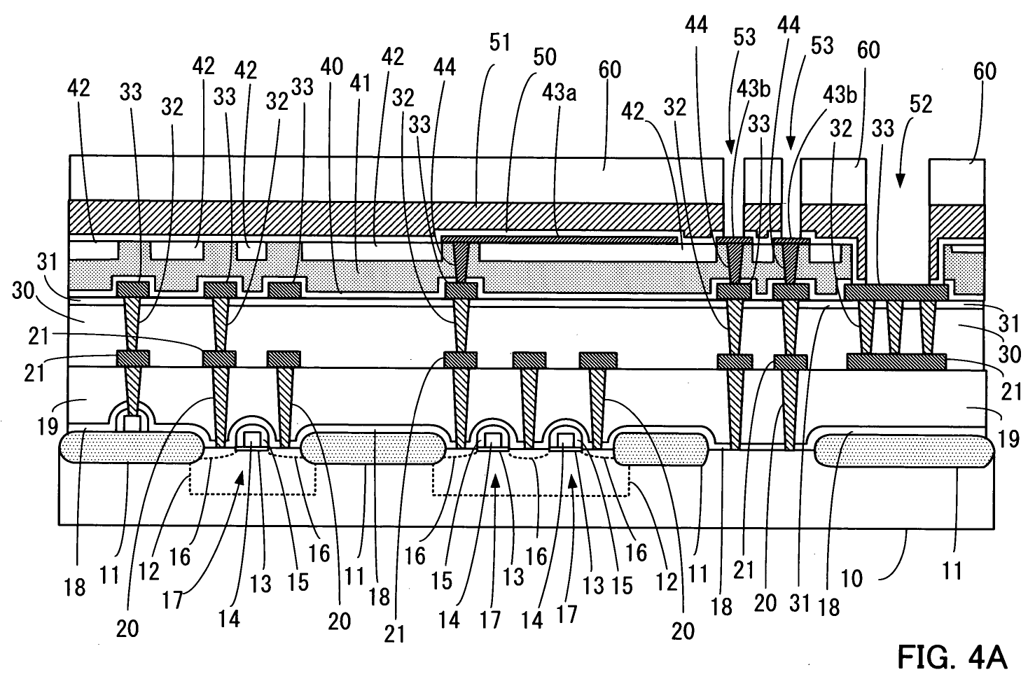

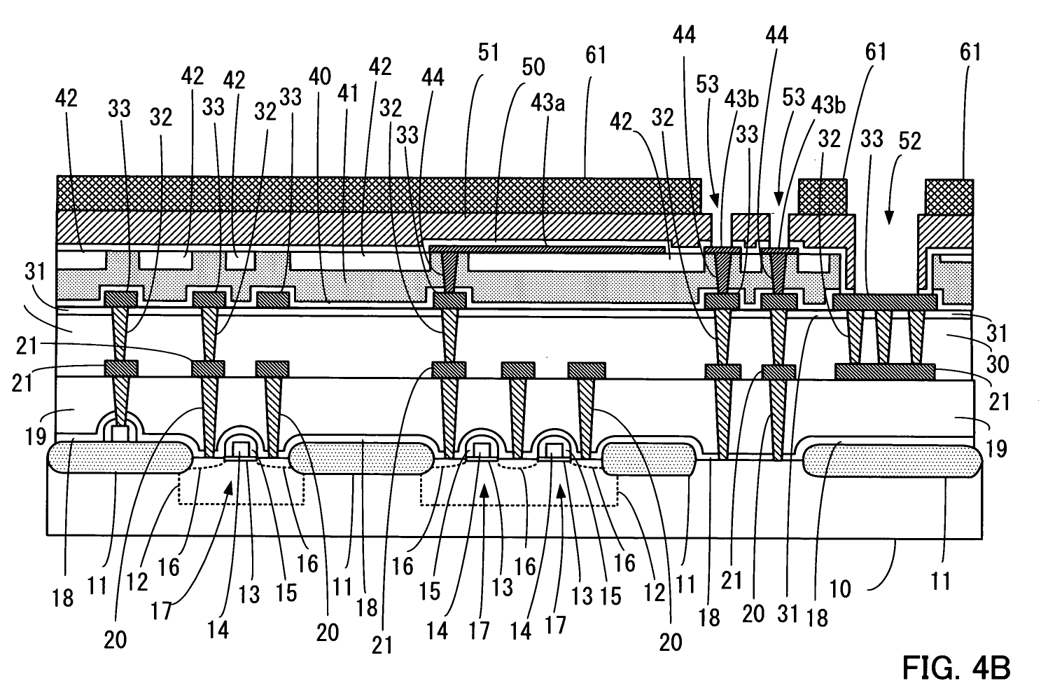

FIG. 4A is a partially schematic sectional view showing the process for fabricating the semiconductor device.

After the SiN film 51 is formed over the TEOS-NSG film 50, photoresist 60 is applied. By performing exposure and development, patterning is performed on the photoresist 60.

The TEOS-NSG film over the pad portion 52 and ESD hole portions 53 is etched with the photoresist 60 on which patterning has been performed as a mask (not shown) to expose the surface of the TiN film 43b in the ESD hole portions 53 and the surface of the Al wiring layer 33 in the pad portion 52.

The photoresist 60 is then dehydrated in a hot furnace in an atmosphere of nitrogen (N₂) at a temperature of 430° C. for 30 minutes.

FIG. 4B is a partially schematic sectional view showing the process for fabricating the semiconductor device.

After the photoresist 60 applied in the preceding process is removed, a nonphotosensitive polyamic ester type polyimide film with a thickness of, for example, 700 nm which is the second passivation film is applied (not shown). By doing so, a nonphotosensitive polyimide film 61 is formed over the SiN film 51. The nonphotosensitive polyimide film 61 is then pre-baked at a temperature of 120 to 150° C. for 120 seconds. Photoresist is applied over the nonphotosensitive polyimide film 61 (not shown). The photoresist is baked. Exposure is then performed to perform patterning on the photoresist and the nonphotosensitive polyimide film 61 at the same time. Only the photoresist is removed by using rinse (not shown). In this case, by performing exposure, patterning is performed on the nonphotosensitive polyimide film 61 formed over the SiN film 51 so that openings will be formed over the pad portion 52 and the ESD hole portions 53. In particular, the area of the opening formed in the nonphotosensitive polyimide film 61 over the ESD hole portions 53 should be larger than that of the top of the TiN film 43b. To be concrete, if the top of the TiN film 43b is 6 μm×6 μm, then the area of the opening formed in the nonphotosensitive polyimide film 61 should be larger than 6 μm×6 μm. More specifically, the diameter of the opening formed in the nonphotosensitive polyimide film 61 over the ESD hole portions 53 should be larger than that of the ESD hole portions 53 and be smaller than or equal to 50 μm.

The nonphotosensitive polyimide film 61 is formed in this way to the edges of the ESD hole portions 53. After that, the nonphotosensitive polyimide film 61 is dried for a while.

To eliminate excess moisture in advance from the nonphotosensitive polyimide film 61, the nonphotosensitive polyimide film 61 is then preheated. To be concrete, the temperature of the nonphotosensitive polyimide film 61 is set to 190 to 240° C. and the nonphotosensitive polyimide film 61 is pre-cured in an atmosphere of N₂ gas, an inert gas (argon (Ar) or carbon dioxide (CO₂)), or mixed gas which contains N₂ gas and an inert gas for 60 to 240 seconds. The reason for setting the temperature of the nonphotosensitive polyimide film 61 to 190 to 240° C. is as follows. If the temperature of the nonphotosensitive polyimide film 61 is higher than 240° C., crosslink tends to occur in nonphotosensitive polyimide molecules. If the temperature of the nonphotosensitive polyimide film 61 is lower than 190° C., the nonphotosensitive polyimide film 61 cannot be dehydrated.

The nonphotosensitive polyimide film 61 is pre-cured in an atmosphere of N₂ gas, an inert gas, or mixed gas which contains N₂ gas and an inert gas, so the phenomenon of the hardening of only part of the nonphotosensitive polyimide film 61 can be avoided.

N₂ gas, an inert gas, or mixed gas which contains N₂ gas and an inert gas is then made to flow into a chamber at a flow rate of 110 l/min or more so that N₂ gas, an inert gas, or mixed gas which contains N₂ gas and an inert gas will fill the chamber. The semiconductor device is then put into the chamber (not shown). To harden the nonphotosensitive polyimide film 61, the temperature of the nonphotosensitive polyimide film 61 is set to 350 to 380° C. and the nonphotosensitive polyimide film 61 is cured in an atmosphere of N₂ gas, an inert gas, or mixed gas which contains N₂ gas and an inert gas for 40 minutes. After the nonphotosensitive polyimide film 61 is cured, the thickness of the nonphotosensitive polyimide film 61 decreases from 700 nm to 500 nm (not shown).

If curing temperature is higher than or equal to 400° C., the Al wiring layers 21 and 33 deform. Accordingly, it is desirable that curing temperature should be set to 380° C. or lower. The polyamic ester type polyimide hardens even at a temperature of about 250° C. However, to promote the dehydration and increase the strength of the nonphotosensitive polyimide film 61, it is desirable that curing temperature should be set to 350° C. or higher. In addition, by performing curing in an atmosphere of N₂ gas, an inert gas, or mixed gas which contains N₂ gas and an inert gas, crosslink in molecules is promoted and the nonphotosensitive polyimide film 61 having sufficient strength can be formed.

To improve resistance to the hygroscopicity of the nonphotosensitive polyimide film 61, the curing should be begun within 120 minutes after the pre-curing. However, if the semiconductor device on the nonphotosensitive polyimide film 61 of which patterning has been performed is left in an atmosphere of N₂ gas and is not exposed to air, then the nonphotosensitive polyimide film 61 may be cured after 120 minutes or more after the pre-curing. For example, after the semiconductor device is kept in a container filled with N₂ gas for 120 minutes or more, the nonphotosensitive polyimide film 61 may be cured. If the semiconductor device is in an atmosphere of N₂ gas, moisture does not exist and is not absorbed by the nonphotosensitive polyimide film 61.

To remove foreign substances which adhere to the surface of the nonphotosensitive polyimide film 61, posttreatment is then performed. In the posttreatment a surface portion of the nonphotosensitive polyimide film 61 is removed to the extent that the nonphotosensitive polyimide film 61 does not suffer damage. To be concrete, ashing is performed on the surface of the nonphotosensitive polyimide film 61 to reduce the thickness of the nonphotosensitive polyimide film 61 by about 45 to 55 nm (not shown).

Ashing is performed under, for example, the following conditions. The temperature of the nonphotosensitive polyimide film 61 is set to 25 to 50° C. and oxygen plasma is used. In this case, an oxygen (O₂) gas flow rate is 600 sccm and discharge power is 600 to 800 W.

After ashing is performed, the nonphotosensitive polyimide film 61 with a final thickness of 450 nm is formed. There is no need to limit the final thickness of the nonphotosensitive polyimide film 61 to 450 nm. The thickness of the nonphotosensitive polyimide film 61 may be adjusted in the above application step and the thickness of the nonphotosensitive polyimide film 61 finally formed should be in the range of 400 to 700 nm.

If photosensitive polyimide is used in place of nonphotosensitive polyimide, the steps of applying photoresist, baking photoresist, performing exposure on photoresist, and removing photoresist which are included in the above steps are not performed. Patterning is performed directly on photosensitive polyimide. As a result, a passivation film including a photosensitive polyimide film can be formed as the top layer of the semiconductor device. For example, the polyamic ester type polyimide is used.

When a finger touches the surface of the semiconductor device, such as a capacitance type fingerprint sensor, which has the above structure, capacitance formed between the TiN film 43a and the surface of finger skin which the passivation film is between is detected by the TiN film 43a which is a sensor electrode, and the shape of irregularities of the surface of the finger skin is detected.

As stated above, the semiconductor device, such as a capacitance type fingerprint sensor, detects capacitance formed between the skin surface and the conductive film between which the insulating layer that is a passivation film including the SiN film and the polyimide film is. The polyimide film with a thickness of 400 to 700 nm is formed as the top layer of the semiconductor device.

By adopting the above method for forming a passivation film, a very thin polyimide film included in a passivation film is formed as the top layer. Accordingly, the distance from the sensor electrode included in the semiconductor device, such as a capacitance type fingerprint sensor, to the surface of the finger skin can be shortened. As a result, capacitance formed between the sensor electrode and the skin surface between which the passivation film is can be increased and sensitivity to detect the irregular shape of a fingerprint can be improved.

A very thin polyimide film is formed. However, curing and posttreatment is adequately performed on the polyimide film, so the polyimide film has superior resistance to hygroscopicity and sufficient mechanical strength. Therefore, the reliability of the semiconductor device is equal to or higher than that of conventional semiconductor devices.

In addition, a very thin polyimide film is formed, so the distance between the ESD hole portion and the surface of the polyimide film is shortened. Therefore, electric charges on the surface of the polyimide film tend to diffuse into the ESD hole portion. As a result, the influence of the electric charges on the capacitance formed between the sensor electrode and the skin surface can be reduced and the sensitivity of a capacitance type fingerprint sensor can be improved.

Furthermore, a thin polyimide film reduces the difference in level between the polyimide film and the ESD hole portion. As a result, the slipping characteristic of the surface of the capacitance type fingerprint sensor becomes good.

Moreover, the polyimide film is formed close to the edge of the ESD hole portion, so the passivation effect of the polyimide film is heightened.

An effect obtained by forming the very thin polyimide film included in the passivation film of the semiconductor device, such as a capacitance type fingerprint sensor, will now be described. To check this effect, three semiconductor devices in which polyimide films of different thicknesses are formed were fabricated.

Three semiconductor devices were prepared. A semiconductor device in which a polyimide film with a thickness of 2,000 nm is formed is a capacitance type fingerprint sensor A, a semiconductor device in which a polyimide film with a thickness of 800 nm is formed is a capacitance type fingerprint sensor B, and a semiconductor device in which a polyimide film with a thickness of 450 nm is formed is a capacitance type fingerprint sensor C. The polyimide film with a thickness of 450 nm is an example of a polyimide film with a thickness of 400 to 700 nm.

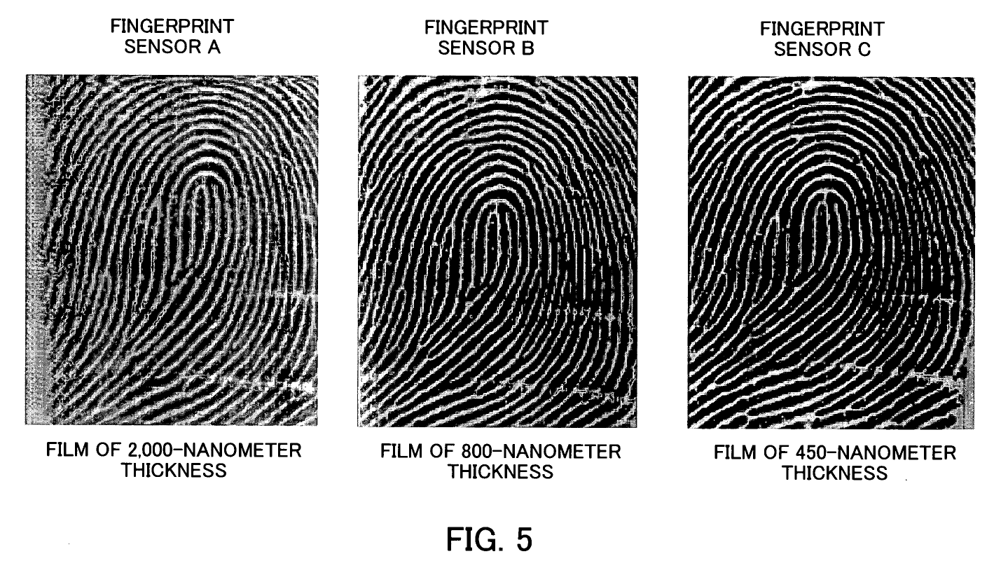

FIG. 5 is a view for describing fingerprint images read by the capacitance type fingerprint sensors.

As can be seen from these images, contrast in the fingerprint image read by the fingerprint sensor A is the flattest. When the fingerprint sensor B is used, contrast becomes better. When the fingerprint sensor C is used, contrast is the best. In particular, when the fingerprint sensor C is used, light and shade which reflects irregularities of a fingerprint is clear and an authentication function will be improved.

In addition, the fingerprint matching ratios of the fingerprint sensors A, B and C were examined. For example, if a capacitance type fingerprint sensor can store 100 dot patterns (it is assumed that each dot pattern is stored by using “0” or “1”. “0” indicates a white portion of an image where a fingerprint does not exist, and “1” indicates a black portion of an image which corresponds to a skin portion), then a finger is made to touch the capacitance type fingerprint sensor and a semiconductor device is made to store a dot pattern of a fingerprint. The finger is made to touch the capacitance type fingerprint sensor again, and a dot pattern of the fingerprint is obtained. A matching ratio indicates how the dot pattern obtained the last time matches the dot pattern obtained this time.

For example, if 80 dots match in 100 dot patterns, then a matching ratio is 80.0%.

The fingerprint matching ratios of the fingerprint sensors A, B and C were 30.3, 56.3, and 87.9% respectively.

It turns out that a reduction in the thickness of a polyimide film improves contrast in a fingerprint image and a matching ratio.

A highly accelerated temperature and humidity stress test (HAST) 1 KH which is a highly accelerated life test and an unbiased highly accelerated temperature and humidity stress test (UHAST) 336 H that is a highly accelerated life test carried out in a state in which a device is not biased were performed on semiconductor devices which are fingerprint sensors C. As a result, there was no fingerprint sensor C which became defective.

The same results that were obtained in the case where the nonphotosensitive polyimide film with a thickness of 450 nm was formed as the passivation film of the fingerprint sensor C were obtained in the case where a photosensitive polyimide film with a thickness of 450 nm was formed as the passivation film of the fingerprint sensor C.

The strength of a very thin polyimide film formed was checked. To check the strength of a very thin polyimide film, two polyimide films of different thicknesses are formed on silicon wafer substrates. A tape test was performed on the polyimide films and stress was measured by a warpage measuring unit.

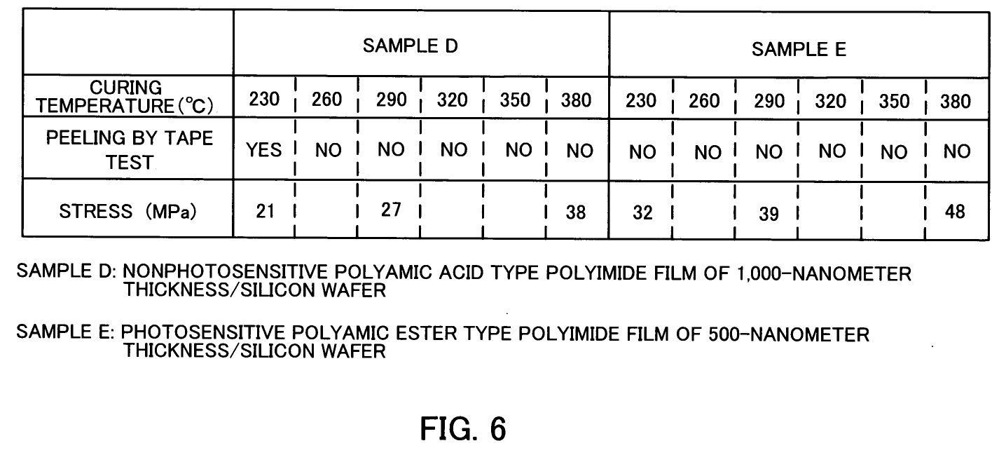

FIG. 6 is a view for describing the strength of the polyimide films.

Two samples D and E were prepared. With the sample D, a nonphotosensitive polyimide film with a thickness of 1,000 nm is formed over the silicon wafer substrate on which an SiN film is formed. With the sample E, a photosensitive polyimide film with a thickness of 500 nm is formed over the silicon wafer substrate on which an SiN film is formed. The photosensitive polyimide film with a thickness of 500 nm is an example of a polyimide film with a thickness of 400 to 700 nm. A photosensitive polyamic ester type polyimide is used for forming the polyimide film of the sample E. With the samples D and E, curing temperature was 230 to 380° C. With the samples D and E, conditions under which pre-curing and posttreatment were performed were the same as those described above.

First, the results of the tape test are as follows. With the sample D cured at a temperature of 260 to 380° C., the polyimide film did not peel. With the sample E cured at a temperature of 230 to 380° C., the polyimide film did not peel off the substrate.

In particular, the tape test showed that with the sample E cured at a temperature lower than a temperature at which the sample D is cured, the polyimide film which does not peel is obtained.

Next, results obtained by measuring stresses in the films with the warpage measuring unit were as follows. A stress created in the sample D cured at a temperature of 230° C. was 21 Mpa. A stress created in the sample D cured at a temperature of 290° C. was 27 Mpa. A stress created in the sample D cured at a temperature of 380° C. was 38 Mpa. A stress created in the sample E cured at a temperature of 230° C. was 32 Mpa. A stress created in the sample E cured at a temperature of 290° C. was 39 Mpa. A stress created in the sample E cured at a temperature of 380° C. was 48 Mpa.

These results indicate that a relatively great stress is created even in the sample E cured at a lower temperature. That is to say, it turns out that the polyimide film of the sample E is stronger than the polyimide film of the sample D.

Results obtained from a sample fabricated by forming a nonphotosensitive polyamic ester type polyimide film with a thickness of 500 nm over a silicon wafer substrate were the same as those obtained from the sample E.

As stated above, it turns out that even if a very thin passivation film is formed as the top layer of the semiconductor device, such as a capacitance type fingerprint sensor, sufficient mechanical strength is obtained.

Objects detected by the above sensor are not limited to fingerprints. For example, the surface of palm skin can easily be detected by using semiconductor devices like that shown in FIG. 4B in large numbers and increasing the area of the sensor.

According to the present invention a method for fabricating a semiconductor device which detects the shape of a skin surface by detecting capacitance formed between the skin surface and a conductive film between which an insulating layer is comprises the step of forming an insulating film with a thickness of not less than 400 nm nor more than 700 nm as a top layer of the semiconductor device.

In addition, according to the present invention a semiconductor device for detecting the shape of a skin surface by detecting capacitance formed between the skin surface and a conductive film between which an insulating layer is comprises an insulating film with a thickness of not less than 400 nm nor more than 700 nm formed as a top layer of the insulating layer.

As a result, a semiconductor device which has sufficient sensitivity, strength, and the like and a method for fabricating such a semiconductor device can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for fabricating a semiconductor device comprising:
a step of forming an insulting film with a thickness of not less than 400 nm nor more than 700 nm as a top layer of the semiconductor device,
wherein the semiconductor device detects the shape of a skin surface by detecting capacitance of the insulting film formed between the skin surface and a conductive film.

2. The method according to claim 1, wherein the insulating film is formed of a polyamic ester type polyimide.

3. The method according to claim 1, wherein the insulating film is cured at a temperature higher than or equal to 350° C. and lower than or equal to 380° C.

4. The method according to claim 3, wherein the insulting film is cured with nitrogen gas, an inert gas, or mixed gas which contains the nitrogen gas and the inert gas of a flow rate of 110 liters/minute or more.

5. The method according to claim 1, further comprising a step of preheating the insulting film at a temperature in a range from 190° C. to 240° C. at not less than 60 seconds nor more than 240 seconds before the insulting film is cured.

6. The method according to claim 5, wherein the preheating is performed in an atmosphere of nitrogen gas, an inert gas, or mixed gas which contains the nitrogen gas and the inert gas.

7. The method according to claim 3, wherein the insulating film is cured within 120 minutes after preheating.

8. The method according to claim 3, wherein after preheating the semiconductor device on which the insulating film is formed is kept in a nitrogen gas, an inert gas, or mixed gas which contains the nitrogen gas and the inert gas.

9. The method according to claim 3, wherein after the insulating film is cured, a surface of the insulating film is removed by ashing to reduce the thickness of the insulating film by not less than 45 nm nor more than 55 nm.

10. The method according to claim 1, wherein the insulating film is formed to an edge of an ESD hole portion formed in the semiconductor device.

11. The method according to claim 2, wherein:
a nonphotosensitive polyamic ester type polyimide is used as the polyamic ester type polyimide for forming the insulating film; and
the method further comprises the steps of:
applying the nonphotosensitive polyamic ester type polyimide to a surface of the semiconductor device,
pre-baking the nonphotosensitive polyamic ester type polyimide applied to the surface of the semiconductor device,
applying photoresist over the nonphotosensitive polyamic ester type polyimide film pre-baked,
performing patterning on the nonphotosensitive polyamic ester type polyimide film with the photoresist as a mask,
drying and pre-curing the nonphotosensitive polyamic ester type polyimide film on which patterning is performed, and
curing the nonphotosensitive polyamic ester type polyimide film pre-cured.

12. The method according to claim 2, wherein:
a photosensitive polyamic ester type polyimide is used as the polyamic ester type polyimide for forming the insulating film; and
the method further comprises the steps of:
applying the photosensitive polyamic ester type polyimide to a surface of the semiconductor device,
pre-baking the photosensitive polyamic ester type polyimide applied to the surface of the semiconductor device,
performing patterning on the photosensitive polyamic ester type polyimide film pre-baked,
drying and pre-curing the photosensitive polyamic ester type polyimide film on which patterning is performed, and
curing the photosensitive polyamic ester type polyimide film pre-cured.

13. The method according to claim 1, wherein a nitride film or an oxide nitride film is formed under the insulating film.

14. A semiconductor device comprising:
detecting a shape of a skin surface by detecting capacitance of an insulting film formed between the skin surface and a conductive film,
wherein the insulting film with a thickness of not less than 400 nm nor more than 700 nm is formed as a top layer of the semiconductor device.

15. The semiconductor device according to claim 14, wherein the insulating film is formed of a polyamic ester type polyimide.

16. The semiconductor device according to claim 14, wherein the insulating film is formed to an edge of an ESD hole portion formed in the semiconductor device.

17. The semiconductor device according to claim 14, wherein a nitride film or an oxide nitride film is formed under the insulating film.

18. The semiconductor device according to claim 16, wherein a diameter of an opening of the insulating film over the ESD hole portion is larger than a diameter of an ESD hole and is smaller than or equal to 50 μm.
